(19) United States
(12) Patent Application Publication
(10) Pub. No.: US 2024/0170306 A1
(43) Pub. Date: May 23, 2024

(54) SUBSTRATE PROCESSING APPARATUS AND METHOD OF PROCESSING A SUBSTRATE USING THE SAME

(71) Applicant: SAMSUNG ELECTRONICS CO., LTD., Suwon-si (KR)

(72) Inventors: Sangjine PARK, Suwon-si (KR); Ji Hwan PARK, Suwon-si (KR); Kuntack LEE, Suwon-si (KR)

(21) Appl. No.: 18/334,075

(22) Filed: Jun. 13, 2023

(30) Foreign Application Priority Data
Nov. 23, 2022 (KR) 10-2022-0158660

(51) Int. Cl. H01L 21/67; H01L 21/687

(52) U.S. Cl. CPC H01L 21/67034; H01L 21/67051; H01L 21/6875; H01L 21/68785

(57) ABSTRACT

A substrate processing apparatus includes a drying chamber housing and a drying chuck in the drying chamber housing. The drying chamber housing includes a lower chamber and an upper chamber attached to the lower chamber. The drying chuck includes first, second, and third supporting members, each connected to the upper chamber and spaced apart from the lower chamber in a first direction. The first supporting member includes a first rod secured to the upper chamber, a first block extending outward from the first rod in a first direction, and a first pin on the first block. The second supporting member includes a second rod secured to the upper chamber, a second block extending outward from the second rod in a second direction, and a second pin on the second block. A distance between the first rod and the second rod may be equal to or larger than 301 mm.

### CROSS-REFERENCE TO RELATED APPLICATIONS

This U.S. non-provisional patent application claims priority under 35 U.S.C. § 119 to Korean Patent Application No. 10-2022-0158660, filed on Nov. 23, 2022, in the Korean Intellectual Property Office, the disclosure of which is hereby incorporated by reference.

### BACKGROUND OF THE INVENTION

The present disclosure relates to a substrate processing apparatus and a method of processing a substrate using the same, and in particular, to a substrate processing apparatus, which is configured to improve fluidity of a supercritical fluid sprayed on a substrate, and a method of processing a substrate using the same.

A process of fabricating a semiconductor device includes various processes. For example, a semiconductor device may be fabricated through a photolithography process, an etching process, a deposition process, and a plating process. A wetting process of supplying a liquid material (e.g., developing solution) on a wafer may be performed during the photolithography process. In addition, a drying process may be performed to remove the liquid material from the wafer. Various methods are being used to form the liquid material on the wafer or to remove the liquid material from the wafer.

### SUMMARY

An embodiment of the inventive concept provides a substrate processing apparatus, which is configured to improve fluidity of a supercritical fluid, and a method of processing a substrate using the same.

An embodiment of the inventive concept provides a substrate processing apparatus, which is configured to facilitate insertion of a substrate, and a method of processing a substrate using the same.

An embodiment of the inventive concept provides a substrate processing apparatus, which is configured to uniformly perform a drying process on a substrate, and a method of processing a substrate using the same.

An embodiment of the inventive concept provides a substrate processing apparatus, which is configured to prevent mechanical damage, which may be caused by collision with a transfer unit, and a method of processing a substrate using the same.

According to an embodiment of the inventive concept, a substrate processing apparatus may include a drying chamber housing defining an internal drying space and a drying chuck in the internal drying space. The drying chamber housing may include a lower chamber and an upper chamber attached to the lower chamber. The drying chuck may include a first supporting member, a second supporting member, and a third supporting member. Each of the first, second, and third supporting members may be connected to the upper chamber and may be spaced apart from the lower chamber in a first direction. The first supporting member may include a first rod having opposite first and second ends, the first end secured to the upper chamber, a first block secured to the first rod second end, the first block extending outward from the first rod in a second direction transverse to the first direction, and a first pin on the first block. The second supporting member may include a second rod having opposite first and second ends, the second rod first end secured to the upper chamber, a second block secured to the second rod second end, the second block extending outward from the second rod in a third direction transverse to the first direction, and a second pin on the second block. A distance between the first rod and the second rod may be equal to or larger than 301 millimeters (mm).

According to an embodiment of the inventive concept, a substrate processing apparatus may include a drying chamber housing including a lower chamber and an upper chamber attached to the lower chamber, and a drying chuck coupled to the upper chamber. The drying chuck may include a first chuck and a second chuck spaced apart from the first chuck. The first chuck may include an elongate first body secured to the upper chamber by first and second spaced apart rods, a first block extending from an end of the first body in a first direction, a second block extending from an opposite end of the first body in the first direction, a first pin on the first block, a second pin on the second block, a first guide member adjacent the first rod and extending from the first body in the first direction, and a second guide member adjacent the second rod and extending from the first body in the first direction.

According to an embodiment of the inventive concept, a substrate processing method may include placing a substrate on a drying chuck in a drying chamber housing and spraying a supercritical fluid toward the substrate. The drying chamber housing may include a lower chamber and an upper chamber attached to the lower chamber. The drying chuck may include a first supporting member, a second supporting member, and a third supporting member. Each of the first, second, and third supporting members may be connected to the upper chamber and may be spaced apart from the lower chamber in a first direction. The first supporting member may include a first rod having opposite first and second ends, the first rod first end secured to the upper chamber, a first block secured to the first rod second end, the first block extending outward from the first rod in a second direction transverse to the first direction, and a first pin on the first block. The second supporting member may include a second rod having opposite first and second ends, the second rod first end secured to the upper chamber, a second block secured to the second rod second end, the second block extending outward from the second rod in a third direction transverse to the first direction, and a second pin on the second block. The placing of the substrate on the drying chuck may include placing the substrate on the first pin and the second pin.

### BRIEF DESCRIPTION OF THE DRAWINGS

FIG. 1 is a schematic diagram illustrating a substrate processing system according to an embodiment of the inventive concept.

FIG. 2 is a sectional view illustrating a cleaning chamber according to an embodiment of the inventive concept.

FIG. 3 is a sectional view illustrating a drying chamber according to an embodiment of the inventive concept.

FIG. 4 is an enlarged sectional view illustrating a portion ‘X’ of FIG. 3.

FIG. 5 is a perspective view illustrating a supporting member according to an embodiment of the inventive concept.

FIG. 6 is a plan view illustrating a substrate disposed on a supporting member according to an embodiment of the inventive concept.

FIG. 7 is a diagram schematically illustrating a supercritical fluid supplying part according to an embodiment of the inventive concept.

FIG. 8 is a flow chart illustrating a substrate processing method according to an embodiment of the inventive concept.

FIGS. 9 to 15 are diagrams sequentially illustrating a substrate processing method according to the flow chart of FIG. 8.

FIG. 16 is a perspective view illustrating a drying chuck according to an embodiment of the inventive concept.

FIG. 17 is a plan view illustrating a drying chuck according to an embodiment of the inventive concept.

### DETAILED DESCRIPTION

Example embodiments of the inventive concepts will now be described more fully with reference to the accompanying drawings, in which example embodiments are shown.

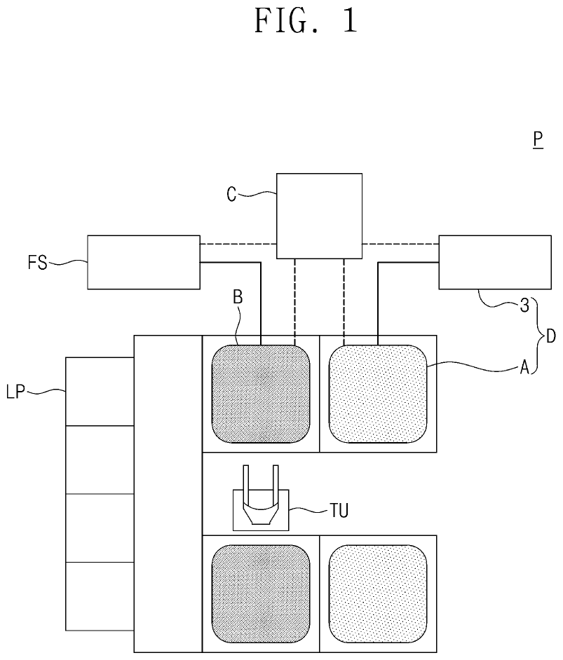

FIG. 1 is a schematic diagram illustrating a substrate processing system according to an embodiment of the inventive concept.

Referring to FIG. 1, a substrate processing system P may be provided. The substrate processing system P may be a system, which is used to process a substrate during a semiconductor fabrication process. More specifically, the substrate processing system P may be a system, which is configured to perform a wetting process or a drying process on the substrate. For example, the substrate processing system P may be used to spray a liquid material on the substrate or perform a wet process on the substrate or may be used to remove a liquid material from a top surface of the substrate or to dry and clean the substrate. For example, the substrate processing system P may be configured to spray developing solution onto a substrate, after an extreme-ultraviolet (EUV) exposure process. In addition, the substrate processing system P may be configured to remove the developing solution from the substrate and to dry the substrate. In the present specification, the term ‘substrate’ may mean a semiconductor wafer. The wafer may be a silicon wafer, but the inventive concept is not limited to this example. The substrate processing system P may include a loading port LP, a wet chamber B, a wetting solution supplying part FS, a transfer unit TU, a substrate processing apparatus D, and a control unit C.

The loading port LP may be a port, on which the substrate is loaded. For example, a substrate, on which various semiconductor fabrication processes are performed, may be loaded on the loading port LP. In an embodiment, a plurality of loading ports LP may be provided. A plurality of substrates may be loaded on each of the loading ports LP. However, in order to reduce complexity in the description, one of the loading ports LP will be described exemplarily, unless the context clearly indicates otherwise.

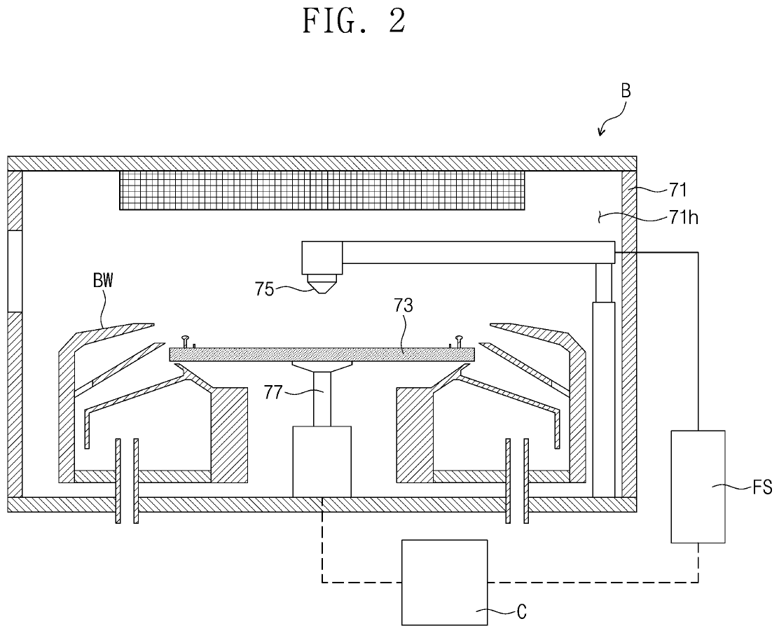

The wet chamber B may be a chamber which is configured to perform a wet process on the substrate. The wet chamber B may provide a space, in which a wet process will be performed. If the substrate is disposed in the wet chamber B, the substrate may be coated with a liquid material (e.g., chemicals and/or isopropyl alcohol (IPA)). The providing of the liquid material may be performed in various manners. For example, by spraying a liquid material on a rotating substrate, it may be possible to realize a uniform distribution of the liquid material, which is formed on the substrate, using centrifugal force. In an embodiment, a plurality of wet chambers B may be provided. For example, a pair of the wet chambers B may be provided. The pair of the wet chambers B may be disposed to face each other. However, in order to reduce complexity in the description, one of the wet chambers B will be described exemplarily. The wet chamber B will be described in more detail with reference to FIG. 2.

The wetting solution supplying part FS may be configured to supply a fluidic material into the wet chamber B. For this, the wetting solution supplying part FS may include a fluid tank, a pump, and so forth. The fluidic material, which is supplied into the wet chamber B by the wetting solution supplying part FS, may be referred to as a wetting solution. The wetting solution may contain various chemicals and/or water. More specifically, the wetting solution may contain developing solution, isopropyl alcohol (IPA), or the like.

The transfer unit TU may be configured to transfer the substrate. For example, the transfer unit TU may be used to transfer a substrate, which is loaded on the loading port LP, to the wet chamber B. In addition, the transfer unit TU may be used to unload the substrate from the wet chamber B and to transfer it to a drying chamber A. For this, the transfer unit TU may include an actuator (e.g., a motor). Although FIG. 1 illustrates an example in which just one transfer unit TU is provided, the inventive concept is not limited to this example.

The substrate processing apparatus D may be configured to dry a substrate. For this, the substrate processing apparatus D may include a drying chamber A and a supercritical fluid supplying part 3.

The drying chamber A may be a chamber, which is used to dry a substrate. For example, the drying chamber A may be configured to perform a drying and/or cleaning process on a substrate unloaded from the wet chamber B. In detail, the drying chamber A may be used to remove a liquid material (e.g., the developing solution and/or IPA), which is left on the substrate when a substrate is unloaded from the wet chamber B, from the substrate. The drying chamber A may provide a space for the drying process. In an embodiment, a plurality of drying chambers A may be provided. For example, a pair of the drying chambers A may be provided. The pair of the drying chambers A may be disposed to face each other. However, in order to reduce complexity in the description, one of the drying chambers A will be described exemplarily.

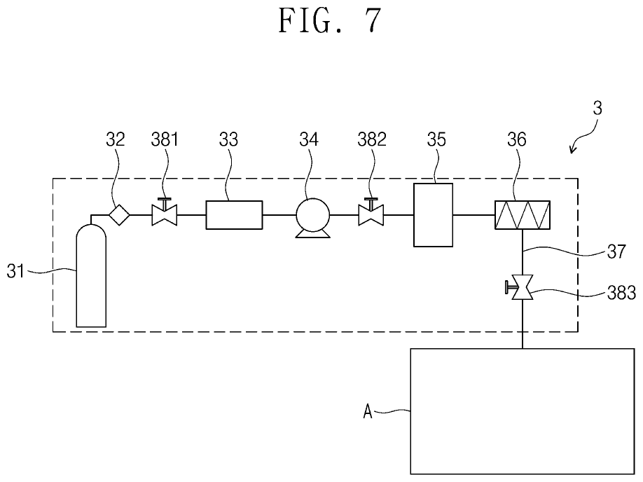

The supercritical fluid supplying part 3 may be configured to supply a fluidic material into the drying chamber A. More specifically, the supercritical fluid supplying part 3 may be configured to supply a supercritical fluid, which will be sprayed into the drying chamber A. For example, the supercritical fluid supplying part 3 may supply carbon dioxide (CO₂), which is in a supercritical fluid (SCF) state, into the drying chamber A. The supercritical fluid supplying part 3 will be described in more detail with reference to FIG. 7.

The control unit C may control the wet chamber B and the drying chamber A. For example, the control unit C may control the supercritical fluid supplying part 3 to adjust an amount of the liquid material left on the substrate. More specifically, the control unit C may control a flow rate of the fluidic material supplied into the drying chamber A.

FIG. 2 is a sectional view illustrating a cleaning chamber according to an embodiment of the inventive concept.

Referring to FIG. 2, the wet chamber B may include a wet chamber housing 71, a wetting stage 73, a wetting nozzle 75, a rotation axis 77, and a bowl BW.

The wet chamber housing 71 may provide a wetting space 71h. When a substrate is disposed in the wetting space 71h, a wet process may be performed on the substrate.

The wetting stage 73 may be placed in the wet chamber housing 71. The wetting stage 73 may support the substrate. In other words, the substrate in the wet chamber housing 71 may be disposed on the wetting stage 73. The wetting stage 73 may be configured to rotate the substrate.

The wetting nozzle 75 may be spaced apart from the wetting stage 73 in an upward direction. The wetting nozzle 75 may be connected to the wetting solution supplying part FS. The wetting nozzle 75 may be configured to spray a wetting solution, which is supplied from the wetting solution supplying part FS, toward the wetting stage 73.

The rotation axis 77 may rotate the wetting stage 73 under the control of the control unit C. The substrate on the wetting stage 73 may be rotated by the rotation axis 77.

The bowl BW may be provided to surround the wetting stage 73. The bowl BW may be used to collect the wetting solution escaping from the wetting stage 73 in an outward direction.

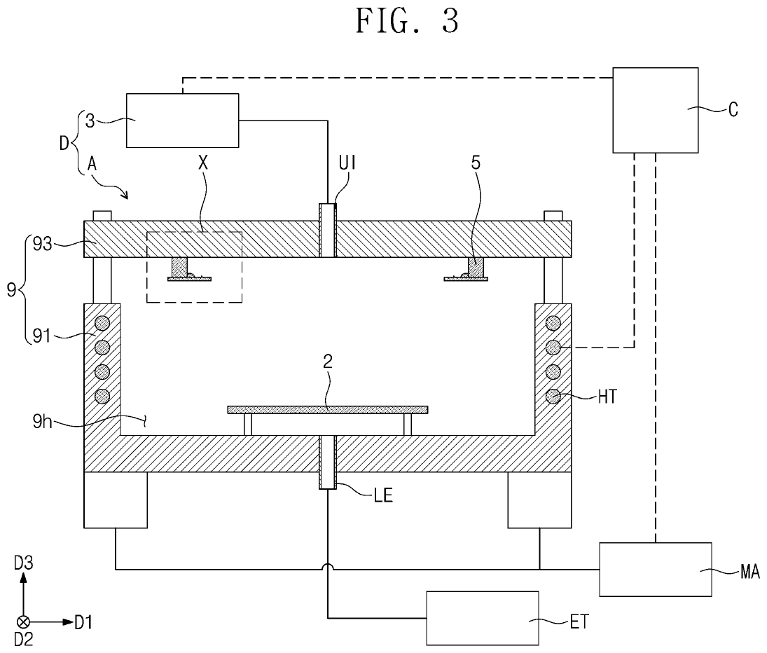

FIG. 3 is a sectional view illustrating a drying chamber according to an embodiment of the inventive concept.

In the present application, the reference numbers D1, D2, and D3 will be used to denote a first direction, a second direction, and a third direction, respectively, which are not parallel to each other. Each of the first and second directions D1 and D2 may be referred to as a horizontal direction. In addition, the third direction D3 may be referred to as a vertical direction.

Referring to FIG. 3, the drying chamber A may be used to dry a substrate. More specifically, the drying chamber A may be used to remove a liquid material from a top surface of the substrate. After a wetting process in the wet chamber B of FIG. 2, a substrate unloaded from the wet chamber B may be dried in the drying chamber A. The drying chamber A may include a drying chamber housing 9, a drying heater HT, a drying chuck 5, a blocking plate 2, a chamber driving unit MA, and an exhausting tank ET.

The drying chamber housing 9 may provide a drying space 9h. The drying chamber housing 9 may include a lower chamber 91 and an upper chamber 93. The lower chamber 91 may be spaced apart from the upper chamber 93 in a downward direction. The drying space 9h may be provided between the lower chamber 91 and the upper chamber 93. The lower chamber 91 may be configured to be movable in upward and downward directions. For example, the lower chamber 91 may be moved in the upward direction by the chamber driving unit MA and may be coupled to the upper chamber 93. In the case where the lower and upper chambers 91 and 93 are coupled to each other, the drying space 9h may be isolated from the outside. An upper injection hole UI may be provided in the upper chamber 93. The upper injection hole UI may be connected to the supercritical fluid supplying part 3. A supercritical fluid may be supplied from the supercritical fluid supplying part 3 into the drying space 9h through the upper injection hole UI. A lower exhausting hole LE may be provided in the lower chamber 91. The lower exhausting hole LE may be connected to the exhausting tank ET. A fluidic material may be exhausted to an outside of the drying chamber housing 9 through the lower exhausting hole LE.

The drying heater HT may be coupled to the drying chamber housing 9. The drying heater HT may be used to heat the drying space 9h. Due to the heating process by the drying heater HT, the supercritical fluid, which is supplied into the drying space 9h, may be maintained in its supercritical state.

The drying chuck 5 may be connected to the upper chamber 93. The drying chuck 5 may be coupled to the upper chamber 93. A substrate may be disposed on the drying chuck 5. In other words, the drying chuck 5 may support the substrate. The drying chuck 5 will be described in more detail below.

The blocking plate 2 may be connected to the lower chamber 91. The blocking plate 2 may be spaced apart from the lower exhausting hole LE by a specific distance in an upward direction. The blocking plate 2 may be used to block the flow of the fluidic material. The chamber driving unit MA may be connected to the lower chamber 91. The chamber driving unit MA may be configured to move the lower chamber 91 in upward and downward directions. The lower chamber 91 may be coupled to or separated from the upper chamber 93 by the chamber driving unit MA. For this, the chamber driving unit MA may include an actuator, such as a motor. The exhausting tank ET may be connected to the lower exhausting hole LE. A fluidic material, which is exhausted through the lower exhausting hole LE, may be transferred to the exhausting tank ET.

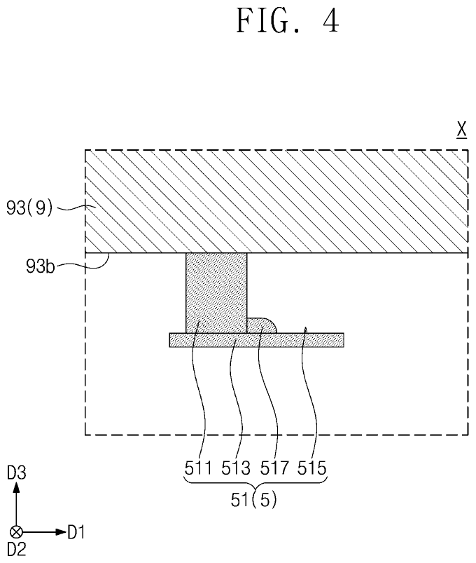

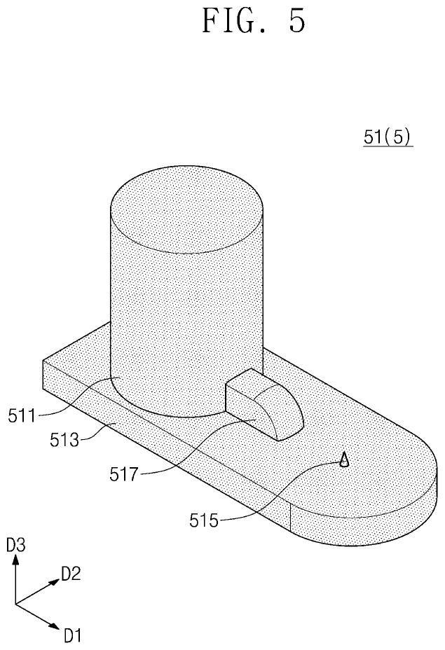

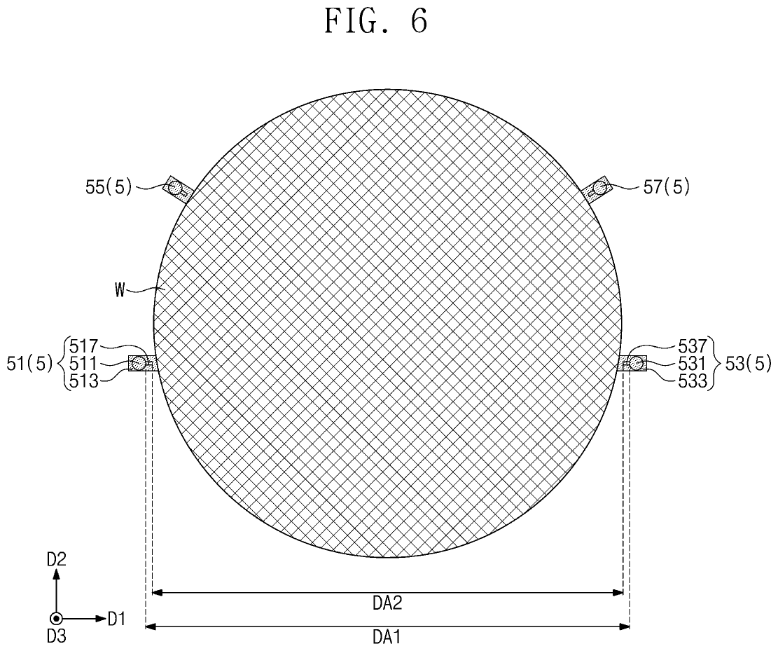

FIG. 4 is an enlarged sectional view illustrating a portion ‘X’ of FIG. 3, FIG. 5 is a perspective view illustrating a supporting member according to an embodiment of the inventive concept, and FIG. 6 is a plan view illustrating a substrate disposed on a supporting member according to an embodiment of the inventive concept.

Referring to FIGS. 4 to 6, the drying chuck 5 may include a first supporting member 51, a second supporting member 53, a third supporting member 55, and a fourth supporting member 57. The first supporting member 51, the second supporting member 53, the third supporting member 55, and the fourth supporting member 57 may be coupled to the upper chamber 93. The first supporting member 51, the second supporting member 53, the third supporting member 55, and the fourth supporting member 57 may be spaced apart from the lower chamber 91 in an upward direction.

The first supporting member 51, the second supporting member 53, the third supporting member 55, and the fourth supporting member 57 may be spaced apart from each other in the horizontal direction. For example, the first supporting member 51, the second supporting member 53, the third supporting member 55, and the fourth supporting member 57 may be arranged in a circumference direction.

Referring to FIGS. 4 and 5, the first supporting member 51 may include a first rod 511, a first block 513, a first pin 515, and a first protruding member 517.

The first rod 511 may be vertically extended. More specifically, the first rod 511 may be extended from a bottom surface 93b of the upper chamber 93 in a downward direction. The first rod 511 may be fixedly coupled to the upper chamber 93. The first rod 511 may have a circular pillar (e.g., a cylindrical column) shape, but the inventive concept is not limited to this example.

The first block 513 may be extended in the horizontal direction. More specifically, the first block 513 may be placed below the first rod 511 and may be extended in the horizontal direction. The first block 513 may have a rectangular parallelepiped shape, but the inventive concept is not limited to this example.

The first pin 515 may be placed on the first block 513. The first pin 515 may be extended from a top surface of the first block 513 in an upward direction. A substrate may be disposed on the first pin 515. In other words, the substrate may be supported by the first pin 515.

The first protruding member 517 may be placed on the first block 513. The first protruding member 517 may be extended from the first rod 511 in the horizontal direction, as illustrated in FIG. 4. More specifically, the first protruding member 517 may be extended from the first rod 511 toward the first pin 515 in the horizontal direction. The first protruding member 517 may be spaced apart from the first pin 515 in the horizontal direction. A length of the first protruding member 517 in the horizontal direction may be equal to or larger than about 4 millimeters (mm), but the inventive concept is not limited to this example. The first protruding member 517 may prevent a substrate from moving in the horizontal direction. For example, in the case where a side surface of the substrate is in contact with the first protruding member 517, the substrate may not move any more.

Each of the second supporting member 53, the third supporting member 55, and the fourth supporting member 57 may be provided to have a structure similar to the first supporting member 51. For example, the second supporting member 53 may include a second rod 531, a second block 533, a second pin 535, and a second protruding member 537.

Referring to FIG. 6, the first rod 511 and the second rod 531 may be spaced apart from each other by a first distance DA1. The first distance DA1 may be the smallest distance between the first rod 511 and the second rod 531. The first distance DA1 may be equal to or larger than about 301 mm. Thus, a substrate having a diameter of 300 mm may pass through a space between the first rod 511 and the second rod 531.

The first protruding member 517 and the second protruding member 537 may be spaced apart from each other by a second distance DA2. The second distance DA2 may be the smallest distance between the first protruding member 517 and the second protruding member 537. The second distance DA2 may be equal to or larger than about 300 mm. More specifically, the second distance DA2 may be equal to or larger than about 301 mm. Thus, a substrate having a diameter of 300 mm may pass through a space between the first protruding member 517 and the second protruding member 537.

FIG. 7 is a diagram schematically illustrating a supercritical fluid supplying part according to an embodiment of the inventive concept.

Referring to FIG. 7, the supercritical fluid supplying part 3 may include a supercritical fluid supplying source 31, a supercritical fluid line 37, a supplying filter 32, a first valve 381, a condenser 33, a pump 34, a second valve 382, a tank 35, a heater 36, and a third valve 383.

The supercritical fluid supplying source 31 may be configured to supply a supercritical fluid. More specifically, the supercritical fluid supplying source 31 may be configured to store and supply a fluidic material, which will be used as a supercritical fluid, in a gas state. In the case where the supercritical fluid is a supercritical carbon dioxide fluid, the supercritical fluid supplying source 31 may store carbon dioxide in a gas state. A temperature of the gaseous carbon dioxide, which is supplied by the supercritical fluid supplying source 31, may range from about 10° C. to about 30° C. In addition, a pressure of the gaseous carbon dioxide, which is supplied by the supercritical fluid supplying source 31, may range from about 4 Megapascals (MPa) to about 6 MPa. The supercritical fluid, which is supplied from the supercritical fluid supplying source 31, may flow through the supercritical fluid line 37.

The supercritical fluid line 37 may constitute a part of a pathway, through which the supercritical fluid is supplied from the supercritical fluid supplying source 31 to the drying chamber A. The supplying filter 32 may be placed on the supercritical fluid line 37. The supplying filter 32 may be configured to remove a foreign material from the supercritical fluid. The first valve 381 may be configured to open and close a conduit line between the supplying filter 32 and the condenser 33 and to control the flow of the supercritical fluid.

The condenser 33 may be configured to cool the carbon dioxide gas, which is supplied from the supercritical fluid supplying source 31. For example, the carbon dioxide gas may be liquefied by the condenser 33. For example, the temperature of the carbon dioxide liquefied by the condenser 33 may range from about 0° C. to 6° C. In addition, the pressure of the carbon dioxide liquefied by the condenser 33 may range from about 4 MPa to 6 MPa.

The pump 34 may be configured to increase the pressure of the supercritical fluid liquefied by the condenser 33. For example, the pressure of the carbon dioxide liquefied by the condenser 33 may be increased to a range from about 15 MPa to 25 MPa by the pump 34. In addition, the temperature of the carbon dioxide liquefied by the condenser 33 may be increased to a range from about 15° C. to 25° C., while passing through the pump 34. The second valve 382 may be configured to open and close a conduit line between the pump 34 and the tank 35 and to control the flow of the supercritical fluid. The tank 35 may store the supercritical fluid, which is compressed by the pump 34.

The heater 36 may be configured to heat the supercritical fluid flowing through the supercritical fluid line 37. More specifically, the heater 36 may be used to heat the liquefied carbon dioxide, which is compressed by the pump 34. As a result of this heating process, the liquefied carbon dioxide may become a supercritical state. The carbon dioxide, which is in a supercritical state by the heater 36, may be in a high-temperature high-pressure state. For example, the temperature of the carbon dioxide, which is in the supercritical state while flowing through the heater 36, may range from about 60° C. to about 90° C. In addition, the pressure of the carbon dioxide, which is in the supercritical state while flowing through the heater 36, may range from about 15 MPa to about 25 MPa. The third valve 383 may be configured to control the flow of the carbon dioxide, which is in the supercritical state while flowing through the heater 36. The carbon dioxide in the supercritical state may be supplied into the drying chamber A through the third valve 383.

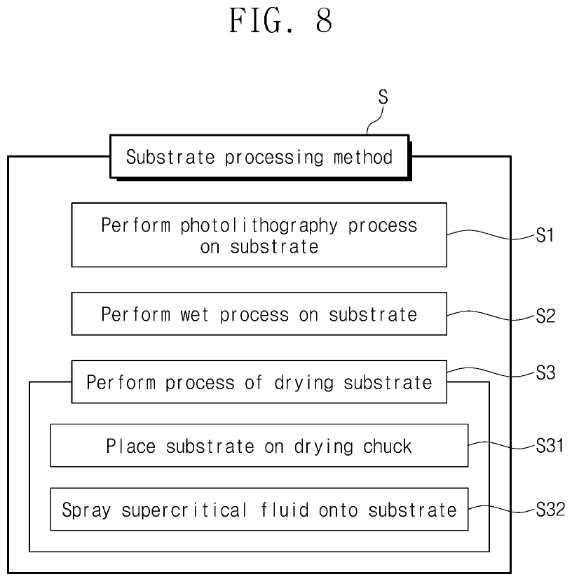

FIG. 8 is a flow chart illustrating a substrate processing method according to an embodiment of the inventive concept.

Referring to FIG. 8, a substrate processing method S may be provided. In the substrate processing method S, the substrate processing system P described with reference to FIGS. 1 to 7 may be used to process a substrate. The substrate processing method S may include performing a photolithography process on the substrate (in S1), performing a wet process on the substrate (in S2), and performing a process of drying the substrate (in S3).

The process of drying the substrate (in S3) may include placing the substrate on a drying chuck (in S31) and spraying a supercritical fluid onto the substrate (in S32).

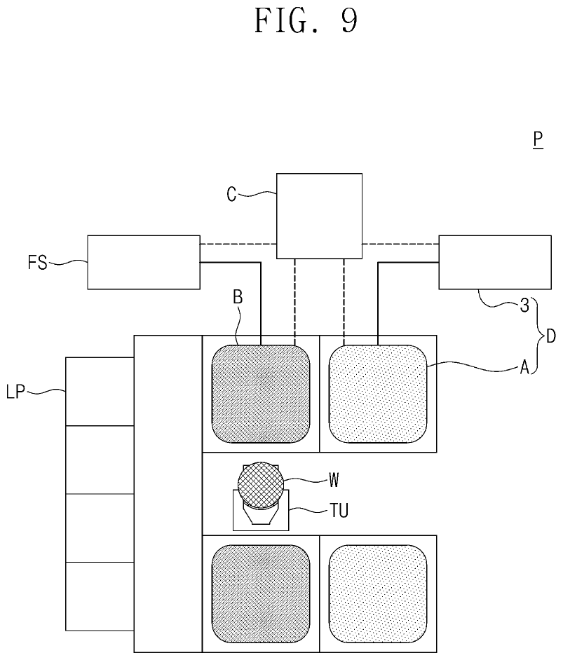

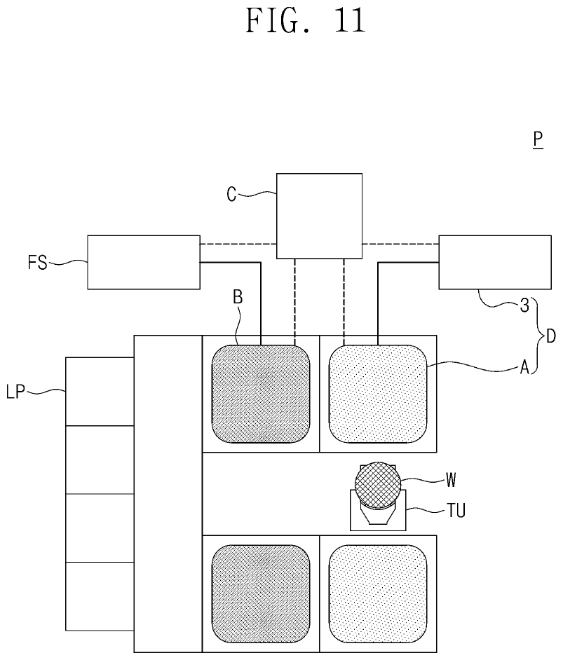

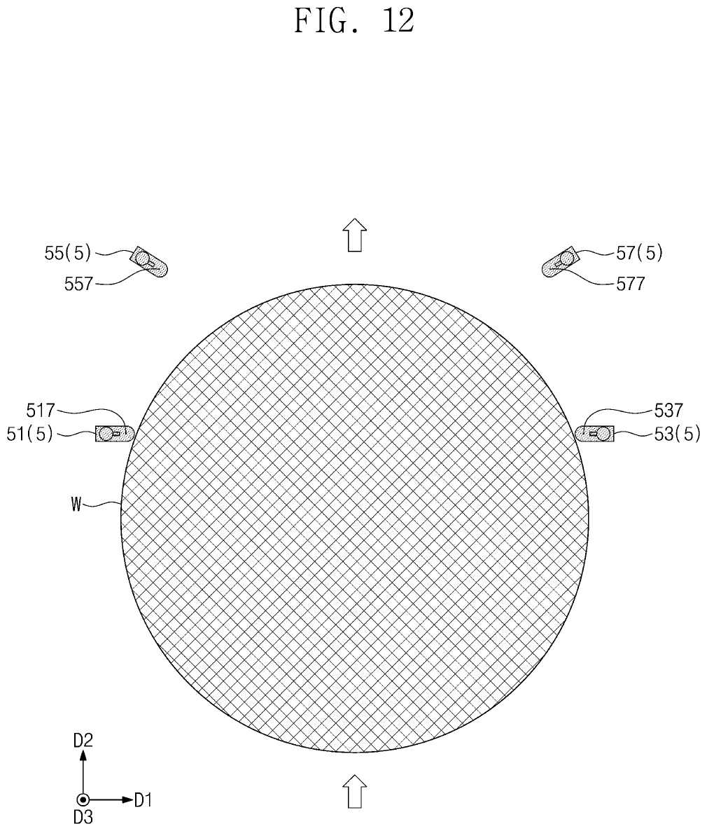

Hereinafter, the substrate processing method S of FIG. 8 will be described in more detail with reference to FIGS. 9 to 15.

FIGS. 9 to 15 are diagrams sequentially illustrating a substrate processing method according to the flow chart of FIG. 8.

Referring to FIG. 8, the photolithography process on the substrate (in S1) may include exposing the substrate, on which a photoresist material is coated, to light. The photolithography process on the substrate (in S1) may be performed using an exposure system that is not illustrated in FIG. 1.

Referring to FIGS. 9 and 8, the wet process on the substrate (in S2) may include placing a substrate W in the wet chamber B using the transfer unit TU. When this process is performed, there may be the coated photoresist material on the substrate W.

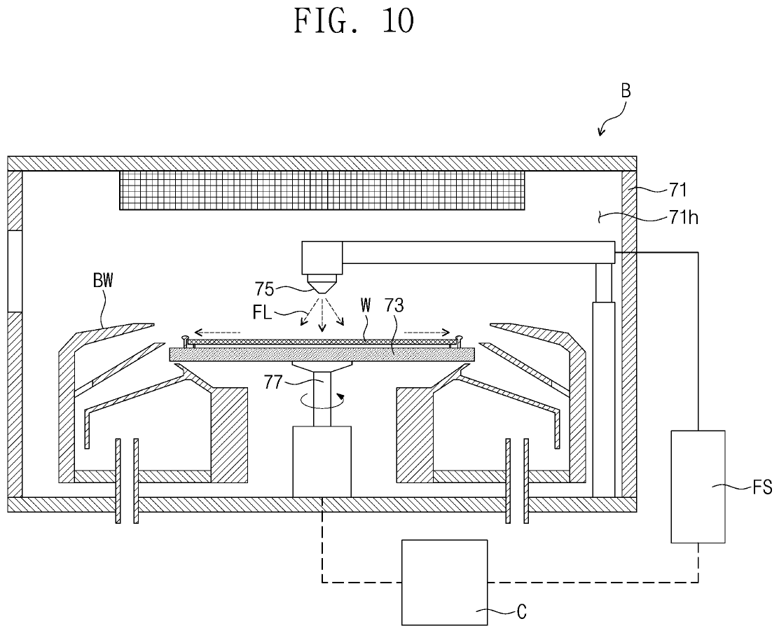

Referring to FIGS. 10 and 8, the wet process on the substrate (in S2) may include spraying a wetting solution FL toward the substrate W placed on the wetting stage 73. For example, the wetting solution FL, which is supplied from the wetting solution supplying part FS, may be sprayed onto the substrate W through the wetting nozzle 75. The substrate W may be rotated during this process. More specifically, the substrate W on the wetting stage 73 may be rotated by rotating the rotation axis 77. Thus, the sprayed wetting solution FL may be formed on the substrate W to uniformly cover the substrate W.

Referring to FIGS. 11, 12, and 8, the placing of the substrate on the drying chuck (in S31) may include moving the substrate W in a horizontal direction to be placed on the drying chuck 5. More specifically, the substrate W may be moved in a horizontal direction and may be inserted into a space between the first rod 511 (e.g., FIG. 6) and the second rod 531. In other words, the substrate W may pass through the space between the first rod 511 and the second rod 531.

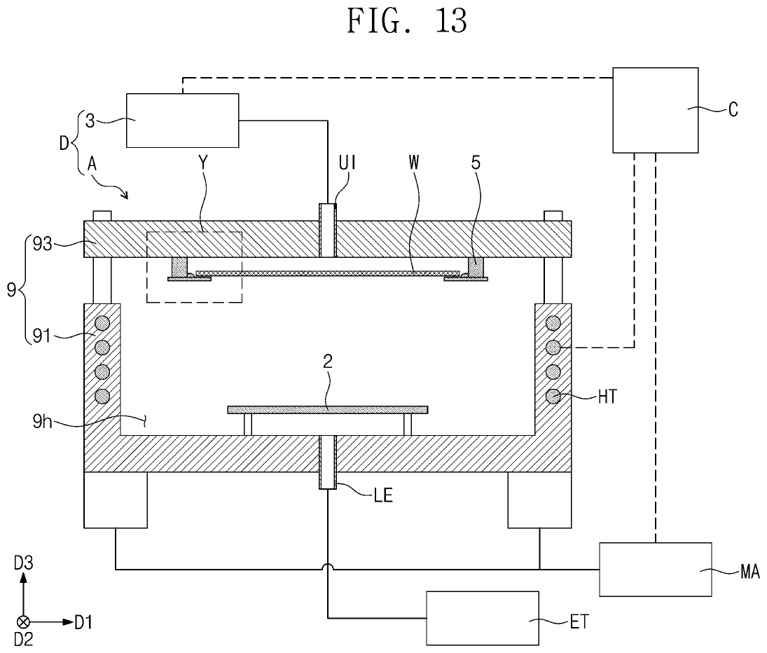

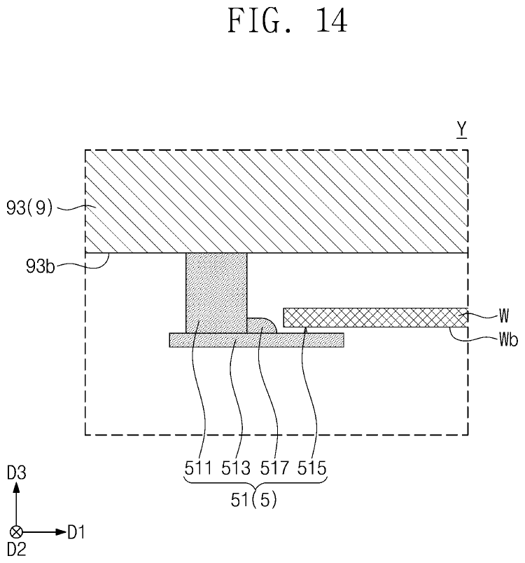

Referring to FIGS. 13 and 14, the substrate W may be disposed on the first supporting member 51, the second supporting member 53, the third supporting member 55, and the fourth supporting member 57. More specifically, the substrate W may be disposed on the first pin 515, a second pin, a third pin, and a fourth pin. A bottom surface of the substrate W may be supported by the first pin 515 and so forth.

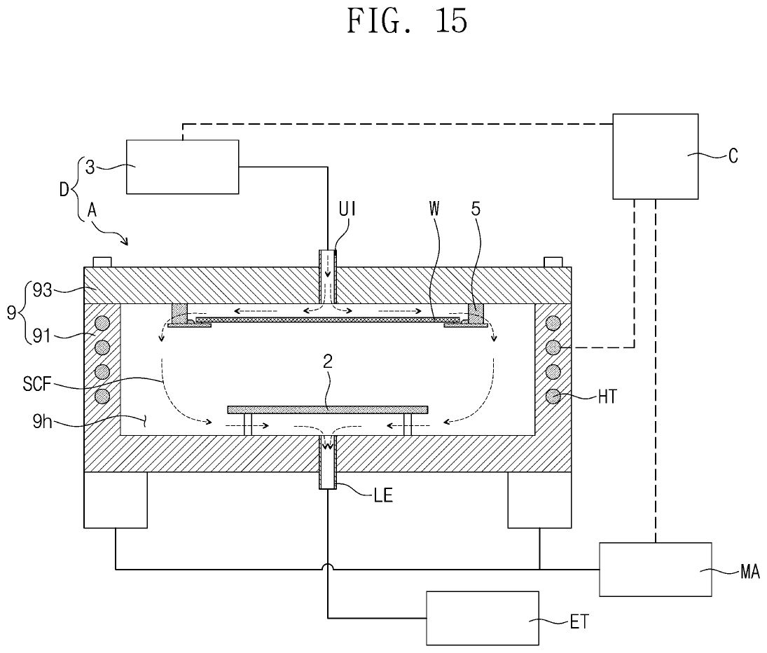

Referring to FIGS. 15 and 8, the spraying of the supercritical fluid onto the substrate (in S32) may include supplying a supercritical fluid SCF into the drying space 9h. The supercritical fluid SCF supplied from the supercritical fluid supplying part 3 may be supplied into the drying chamber housing 9. A fluidic material, which is supplied from the supercritical fluid supplying part 3, may be injected into the upper injection hole UI. The supercritical fluid SCF, which is supplied through the drying space 9h, may be used to remove a liquid material from the substrate W. For example, the wetting solution, which is formed on the substrate W in the wet chamber B (e.g., see FIG. 10), may be removed by the supercritical fluid SCF in the drying chamber A. More specifically, a liquid material on the substrate W may be removed by the supercritical fluid SCF, which is in a high pressure state, and thus, the substrate W may be dried.

In a substrate processing apparatus according to an example embodiment of the inventive concept and a method of processing a substrate using the same, it may be possible to secure a sufficiently large space between supporting members. Thus, a supercritical fluid, which is sprayed onto a top surface of the substrate, may be effectively exhausted to an outside of the substrate. Accordingly, it may be possible to improve the fluidity of the supercritical fluid.

In a substrate processing apparatus according to an example embodiment of the inventive concept and a method of processing a substrate using the same, a supercritical fluid may be exhausted to the outside, while having a symmetric distribution on a substrate. Thus, it may be possible to realize a uniform distribution of the supercritical fluid on the substrate and thereby to uniformly dry the substrate.

In a substrate processing apparatus according to an example embodiment of the inventive concept and a method of processing a substrate using the same, a distance between two supporting members may be larger than a diameter of a substrate. Thus, a substrate may be smoothly inserted into a space between supporting members fastened to an upper chamber.

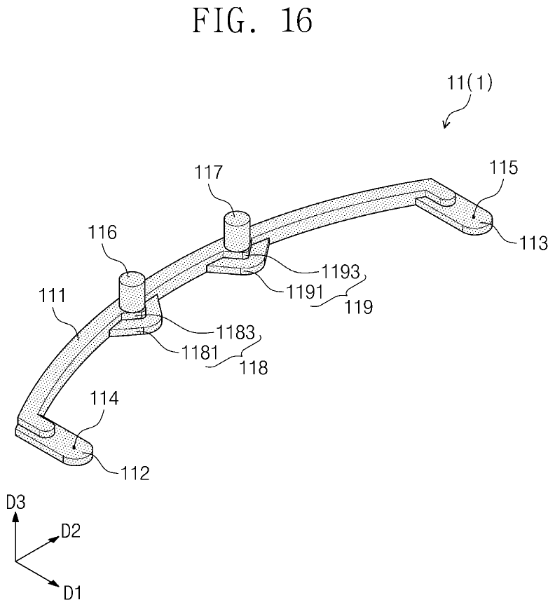

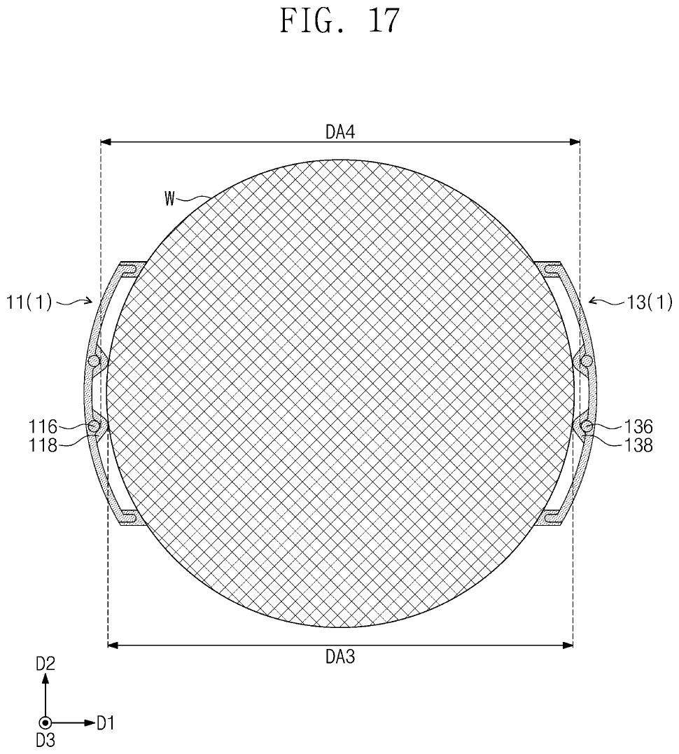

FIG. 16 is a perspective view illustrating a drying chuck according to an embodiment of the inventive concept, and FIG. 17 is a plan view illustrating a drying chuck according to an embodiment of the inventive concept.

In the following description, for concise description, an element previously described with reference to FIGS. 1 to 15 may be identified by the same reference number without repeating an overlapping description thereof.

Referring to FIGS. 16 and 17, a drying chuck 1 may be provided. The drying chuck 1 may be fixedly coupled to the bottom surface of the upper chamber 93 (e.g., see FIG. 3). The drying chuck 1 may include a first chuck 11 and a second chuck 13. The first chuck 11 and the second chuck 13 may be spaced apart from each other in the first direction D1.

The first chuck 11 may include a first body 111, a first block 112, a second block 113, a first pin 114, a second pin 115, a first rod 116, a second rod 117, a first guide member 118, and a second guide member 119.

The first body 111 may be extended in the second direction D2. The first body 111 may have a curved shape, which is curved in the first direction D1 when viewed in a plan view. For example, the first body 111 may be an arch-shaped rod, which is curved in the first direction D1.

The first block 112 may be extended from an end of the first body 111 in the first direction D1. A top surface of the first block 112 may be located at a level that is lower than a top surface of the first body 111.

The second block 113 may be extended from an opposite end of the first body 111 in the first direction D1. A top surface of the second block 113 may be located at a level that is lower than the top surface of the first body 111. The second block 113 may be spaced apart from the first block 112 in the second direction D2.

The first pin 114 may be placed on the first block 112. The first pin 114 may protrude from the top surface of the first block 112 in an upward direction. The first pin 114 may be spaced apart from the first body 111 in the horizontal direction.

The second pin 115 may be placed on the second block 113. The second pin 115 may protrude from the top surface of the second block 113 in an upward direction. The second pin 115 may be spaced apart from the first body 111 in the horizontal direction.

The first rod 116 may be extended from the first body 111 in an upward direction. The first rod 116 may be placed between the first block 112 and the second block 113. The first rod 116 may be fixedly coupled to the upper chamber 93. The first body 111 may be connected to the upper chamber 93 by the first rod 116.

The second rod 117 may be extended from the first body 111 in an upward direction. The second rod 117 may be placed between the first block 112 and the second block 113. The second rod 117 may be spaced apart from the first rod 116 in the second direction D2. The second rod 117 may be fixedly coupled to the upper chamber 93. The first body 111 may be connected to the upper chamber 93 by the second rod 117.

The first guide member 118 may be placed below the first rod 116. The first guide member 118 may protrude from the first body 111 in the first direction D1. The first guide member 118 may have a triangle shape, when viewed in a plan view, but the inventive concept is not limited to this example. The first guide member 118 may include a first lower member 1181 and a first upper member 1183. An area of the first lower member 1181 may be larger than an area of the first upper member 1183. Accordingly, a top surface of the first lower member 1181 may be partially exposed.

The second guide member 119 may be placed below the second rod 117. The second guide member 119 may protrude from the first body 111 in the first direction D1, as illustrated in FIG. 16. The second guide member 119 may be spaced apart from the first guide member 118 in the second direction D2, as illustrated in FIG. 16. The second guide member 119 may have a triangle shape, when viewed in a plan view, but the inventive concept is not limited to this example. The second guide member 119 may include a second lower member 1191 and a second upper member 1193. An area of the second lower member 1191 may be larger than an area of the second upper member 1193. Thus, a top surface of the second lower member 1191 may be partially exposed.

The second chuck 13 may have a structure similar to the first chuck 11. For example, the second chuck 13 may also include a second body, a third block, a fourth block, a third pin, a fourth pin, a third rod 136, a fourth rod, a third guide member 138, and a fourth guide member.

The third guide member 138 and the first guide member 118 may be spaced apart from each other by a third distance DA3, as illustrated in FIG. 17. The third distance DA3 may be the smallest horizontal distance between the third guide member 138 and the first guide member 118. The third distance DA3 may be equal to or larger than about 301 mm. Thus, a substrate having a diameter of 300 mm may pass through a space between the third guide member 138 and the first guide member 118.

The third rod 136 and the first rod 116 may be spaced apart from each other by a fourth distance DA4, as illustrated in FIG. 17. The fourth distance DA4 may be the smallest horizontal distance between the third rod 136 and the first rod 116. The fourth distance DA4 may be equal to or larger than about 301 mm. Thus, a substrate having a diameter of 300 mm may pass through a space between the third rod 136 and the first rod 116.

In a substrate processing apparatus according to an example embodiment of the inventive concept and a method of processing a substrate using the same, one drying chuck may be fastened to an upper chamber by two rods. Thus, even when, in a step of loading a substrate on the drying chuck, a transfer unit collides with the drying chuck, it may be possible to prevent the drying chuck from being damaged or deformed. Hence, the process can be performed in a more stable manner.

In a substrate processing apparatus according to an example embodiment of the inventive concept and a method of processing a substrate using the same, two guide members may be disposed in one drying chuck to be spaced apart from each other. Thus, it may be possible to secure a sufficiently large space between the substrate and the drying chuck. Thus, a supercritical fluid, which is sprayed onto a top surface of the substrate, may be effectively exhausted to an outside of the substrate. Accordingly, it may be possible to improve the fluidity of the supercritical fluid.

In a substrate processing apparatus according to an embodiment of the inventive concept and a method of processing a substrate using the same, it may be possible to improve fluidity of a supercritical fluid.

In a substrate processing apparatus according to an embodiment of the inventive concept and a method of processing a substrate using the same, it may be possible to facilitate insertion of a substrate.

In a substrate processing apparatus according to an embodiment of the inventive concept and a method of processing a substrate using the same, it may be possible to uniformly perform a drying process on a substrate.

In a substrate processing apparatus according to an embodiment of the inventive concept and a method of processing a substrate using the same, it may be possible to prevent mechanical damage, which may be caused by collision with a transfer unit.

While example embodiments of the inventive concept have been particularly shown and described, it will be understood by one of ordinary skill in the art that variations in form and detail may be made therein without departing from the scope of the attached claims.

What is claimed is:

1. A substrate processing apparatus, comprising:
a drying chamber housing defining an internal drying space; and
a drying chuck in the internal drying space,
wherein the drying chamber housing comprises:
a lower chamber; and
an upper chamber attached to the lower chamber,
wherein the drying chuck comprises a first supporting member, a second supporting member, and a third supporting member,
wherein each of the first, second, and third supporting members is connected to the upper chamber and is spaced apart from the lower chamber in a first direction,
wherein the first supporting member comprises:
a first rod having opposite first and second ends, the first end secured to the upper chamber;
a first block secured to the first rod second end, the first block extending outward from the first rod in a second direction transverse to the first direction; and
a first pin on the first block,
wherein the second supporting member comprises:
a second rod having opposite first and second ends, the second rod first end secured to the upper chamber;
a second block secured to the second rod second end, the second block extending outward from the second rod in a third direction transverse to the first direction; and
a second pin on the second block, and
wherein a distance between the first rod and the second rod is equal to or larger than 301 mm.

2. The substrate processing apparatus of claim 1, wherein the third supporting member comprises:
a third rod having opposite first and second ends, the third rod first end secured to the upper chamber;
a third block secured to the third rod second end, the third block extending outward from the third rod in a fourth direction transverse to the first direction; and
a third pin on the third block.

3. The substrate processing apparatus of claim 1, wherein the drying chuck further comprises a fourth supporting member, which is connected to the upper chamber and is spaced apart from the lower chamber in the first direction.

4. The substrate processing apparatus of claim 1, wherein the first supporting member further comprises a first protruding member on the first block,
wherein the first protruding member extends from the first rod toward the first pin, and
wherein the first protruding member and the first pin are spaced apart from each other.

5. The substrate processing apparatus of claim 4, wherein the second supporting member further comprises a second protruding member on the second block,
wherein the second protruding member extends from the second rod toward the second pin, and
wherein the second protruding member and the second pin are spaced apart from each other.

6. The substrate processing apparatus of claim 5, wherein a distance between the first protruding member and the second protruding member is equal to or larger than 301 mm.

7. The substrate processing apparatus of claim 4, wherein a length of the first protruding member is equal to or larger than 4 mm.

8. The substrate processing apparatus of claim 1, wherein the first, second, and third supporting members are spaced apart from each other.

9. A substrate processing apparatus, comprising:
a drying chamber housing comprising a lower chamber and an upper chamber attached to the lower chamber; and
a drying chuck coupled to the upper chamber,
wherein the drying chuck comprises a first chuck and a second chuck spaced apart from the first chuck,
wherein the first chuck comprises:
an elongate first body secured to the upper chamber by first and second spaced apart rods;
a first block extending from an end of the first body in a first direction;
a second block extending from an opposite end of the first body in the first direction;
a first pin on the first block;
a second pin on the second block;
a first guide member adjacent the first rod and extending from the first body in the first direction; and
a second guide member adjacent the second rod and extending from the first body in the first direction.

10. The substrate processing apparatus of claim 9, wherein the first guide member comprises:
a first lower member; and
a first upper member on the first lower member,
wherein an area of the first lower member is larger than an area of the first upper member such that a top surface of the first lower member is exposed.

11. The substrate processing apparatus of claim 9, wherein each of the first and second guide members has a triangle shape, when viewed in a plan view.

12. The substrate processing apparatus of claim 9, wherein the second chuck comprises:
an elongate second body secured to the upper chamber by third and fourth spaced apart rods;
a third block extending from an end of the second body;
a fourth block extending from an opposite end of the second body;
a third pin on the third block;
a fourth pin on the fourth block.

13. The substrate processing apparatus of claim 12, wherein a distance between the third rod and the first rod is equal to or larger than 301 mm.

14. The substrate processing apparatus of claim 9, wherein the first body has a curved shape.

15. The substrate processing apparatus of claim 9, further comprising a supercritical fluid supplying part configured to supply a supercritical fluid into the drying chamber housing.

16. A substrate processing method, comprising:
placing a substrate on a drying chuck in a drying chamber housing; and
spraying a supercritical fluid toward the substrate,
wherein the drying chamber housing comprises a lower chamber and an upper chamber attached to the lower chamber,
wherein the drying chuck comprises a first supporting member, a second supporting member, and a third supporting member,
wherein each of the first, second, and third supporting members is connected to the upper chamber and is spaced apart from the lower chamber in a first direction,
wherein the first supporting member comprises:
a first rod having opposite first and second ends, the first rod first end secured to the upper chamber;
a first block secured to the first rod second end, the first block extending outward from the first rod in a second direction transverse to the first direction; and
a first pin on the first block,
wherein the second supporting member comprises:
a second rod having opposite first and second ends, the second rod first end secured to the upper chamber;
a second block secured to the second rod second end, the second block extending outward from the second rod in a third direction transverse to the first direction; and
a second pin on the second block, and
wherein the placing of the substrate on the drying chuck comprises placing the substrate on the first pin and the second pin.

17. The method of claim 16, wherein a distance between the first rod and the second rod is equal to or larger than 301 mm.

18. The method of claim 17, wherein the placing of the substrate on the drying chuck further comprises inserting the substrate into a region between the first rod and the second rod.

19. The method of claim 16, further comprising performing a wet process on the substrate, before the placing of the substrate on the drying chuck.

20. The method of claim 19, further comprising performing a photolithography process on the substrate, before the performing the wet process on the substrate.
